(19) United States
(12) Patent Application Publication
(10) Pub. No.: US 2020/0379337 A1
(43) Pub. Date: Dec. 3, 2020

(54) BLANKMASK AND PHOTOMASK

(71) Applicant: S&S TECH Co., Ltd., Daegu-si (KR)

(72) Inventors: Cheol SHIN, Daegu-si (KR); Jong-Hwa LEE, Daegu-si (KR); Chul-Kyu YANG, Daegu-si (KR); Min-Ki CHOI, Daegu-si (KR); Seung-Hyup SHIN, Daegu-si (KR)

(73) Assignee: S&S TECH Co., Ltd., Daegu-si (KR)

(21) Appl. No.: 15/931,380

(22) Filed: May 13, 2020

(30) Foreign Application Priority Data
May 31, 2019 (KR) 10-2019-0064314
Dec. 5, 2019 (KR) 10-2019-0160462

(51) Int. Cl. G03F 1/26; G03F 1/48; G03F 1/60; G03F 1/80; H01L 21/033

(52) U.S. Cl. CPC G03F 1/26; G03F 1/48; H01L 21/0332; G03F 1/80; G03F 1/60

(57) ABSTRACT

A blankmask includes a transparent substrate, a phase-shift film, and a light-shielding film. The phase-shift film for example has a transmissivity of 30˜100%, and in this case the light-shielding film has a thickness of 40˜70 nm and a composition ratio of 30˜80 at % chromium, 10˜50 at % nitrogen, 0˜35% oxygen, and 0˜25% carbon. A structure where the light-shielding film and the phase-shift film are stacked has an optical density of 2.5˜3.5. Thus, CD deviation is minimized when the light-shielding film is etched in a manufacturing process for a photomask.

### CROSS-REFERENCE TO RELATED THE APPLICATION

This application claims priority from Korean Patent Application Nos. 10-2019-0064314 filed on May 31, 2019 and 10-2019-0160462 filed on Dec. 5, 2019 in the Korean Intellectual Property Office, the disclosure of which is incorporated herein by reference.

### BACKGROUND

### Field

The disclosure relates to a blankmask and a photomask, and more particularly to a blankmask and a photomask which have high quality with a critical dimension (CD) deviation controlled by controlling an etching speed of a light-shielding film.

### Description of the Related Art

With high integration of a semiconductor circuit, a liquid crystal display device, etc. semiconductor processing technology has recently been required to have a high degree of pattern precision, and thus a photomask having information about a circuit original and a blankmask to be used as a prototype of the photomask have become increasingly important.

The blankmask is broadly classified into two of a binary blankmask and a phase-shift blankmask. The binary blankmask includes a light-shielding film on a transparent substrate, and the phase-shift blankmask includes a phase-shift film and a light-shielding film which are stacked in sequence on a transparent substrate.

Recently, a blankmask with a hard-mask film on a light-shielding film has been developed and mass-produced. Such a blankmask makes it possible to form a resist film thinner than that of the blankmask having no hard-mask films, and is effective in improving resolution and critical dimension (CD) linearity with a less loading effect as an inorganic hard-mask film is used to etch a thin film below.

A procedure of manufacturing the photomask by the blankmask having the hard-mask film is as follows.

First, in a case of the binary blankmask, a resist film pattern is formed through writing and developing processes, and then the resist film pattern is used as an etch mask in performing an etching process, thereby forming a hard-mask film pattern. Next, the hard-mask film pattern is used as an etch mask in performing an etching process, thereby forming a light-shielding film pattern. Subsequently, the hard-mask film pattern is removed to thereby form the photomask.

On the other hand, in a case of the phase-shift blankmask, a resist film pattern is formed through writing and developing processes, and then the resist film pattern is used as an etch mask to form a hard-mask film pattern. The hard-mask film pattern is used as an etch mask to form a light-shielding film pattern, and then a phase-shift film pattern is formed through an etching process using the hard-mask film and light-shielding film patterns.

When the phase-shift blankmask is used in manufacturing the photomask, a problem arises as follows.

First, the light-shielding film made of a chromium (Cr)-based material shows a tendency to be relatively isotropically etched by a radical reaction when dry-etched with chlorine (Cl)-based gas during the above processes. Specifically, when the light-shielding film is etched to form the light-shielding film pattern, the isotropic etching characteristic of the radical reaction causes a deviation in CD between the resist film and the light-shielding film pattern. The blankmask having the hard-mask film is decreased in the CD deviation as compared with the blankmask using only a resist pattern without the hard-mask film in patterning the light-shielding film, but the light-shielding film pattern still has a CD deviation higher than a certain level as compared with the CD of the hard-mask film pattern.

As the difference between the CD of the final pattern, i.e., the phase-shift film pattern expected by the photomask manufacturing process and the CD initially obtained by exposing the resist film becomes greater, an error is higher likely to occur, thereby resulting in deteriorating a process window margin and thus causing problems in resolution, CD mean-to-target (MTT), and CD precision control.

### SUMMARY

Accordingly, an aspect of the disclosure is to provide a blankmask which can minimize a CD deviation when a light-shielding film is etched in a photomask manufacturing process.

According to one embodiment of the disclosure, there is provided a blankmask including: a transparent substrate; and a light-shielding film formed on the transparent substrate, the light-shielding film having a composition ratio of 20˜70 at % chromium, 15˜55 at % nitrogen, 0˜40 at % oxygen, and 0˜30 at % carbon.

The blankmask may further include a phase-shift film formed on the transparent substrate and beneath the light-shielding film. In this case, the phase-shift film may have a transmissivity of 3˜10% with respect to exposure light, a structure where the light-shielding film and the phase-shift film are stacked may have an optical density of 2.5˜3.5, and the light-shielding film may have a thickness of 30˜70 nm.

According to another embodiment of the disclosure, there is provided a blankmask including: a transparent substrate; a phase-shift film formed on the transparent substrate; and a light-shielding film formed on the phase-shift film, the phase-shift film having a transmissivity of 30˜100%, and the light-shielding film having a composition ratio of 30˜80 at % chromium, 10˜50 at % nitrogen, 0˜35% oxygen, and 0˜25% carbon. A structure where the light-shielding film and the phase-shift film are stacked may have an optical density of 2.5˜3.5, and the light-shielding film may have a thickness of 40˜70 nm.

According to another embodiment of the disclosure, there is provided a blankmask including: a transparent substrate; a phase-shift film formed on the transparent substrate; and a light-shielding film formed on the phase-shift film, the phase-shift film having a transmissivity of 10˜30%, and the light-shielding film having a composition ratio of 25˜75 at % chromium, 5˜45 at % nitrogen, 0˜30% oxygen, and 0˜20% carbon. A structure where the light-shielding film and the phase-shift film are stacked may have an optical density of 2.5˜3.5, and the light-shielding film may have a thickness of 35˜65 nm.

Meanwhile, the light-shielding film may include a multi-layer including two or more layers.

When the light-shielding film includes two layers of an upper layer and a lower layer, the lower layer may have a slower etching speed than the upper layer.

Further, when the light-shielding film includes three layers of an upper layer, a middle layer, and a lower layer, the middle layer may have a slower etching speed than the upper layer and the lower layer, or the middle layer and the lower layer may have a slower etching speed than the upper layer. To this end, the upper layer may include nitrogen (N) and oxygen (O). Further, the lower layer may have a faster etching speed than the middle layer, and, to this end, the lower layer may include more nitrogen (N) and/or oxygen (O) than the middle layer.

Meanwhile, the phase-shift film may include silicon (Si) or a silicon (Si)-based material including transition metal.

Further, the blankmask may further include a hard-mask film formed on the light-shielding film, and in this case the hard-mask film may include silicon (Si) or a silicon (Si)-based material including transition metal.

According to another embodiment of the disclosure, there is provided a photomask manufactured using the foregoing blankmask.

### BRIEF DESCRIPTION OF THE DRAWINGS

The above and/or other aspects will become apparent and more readily appreciated from the following description of exemplary embodiments, taken in conjunction with the accompanying drawings, in which

FIG. 1 illustrates a structure of a blankmask according to an embodiment of the disclosure; and

FIG. 2 illustrates a structure of a blankmask according to another embodiment of the disclosure.

### DETAILED DESCRIPTION OF EXEMPLARY EMBODIMENTS

Although a few embodiments are described below in detail, the embodiments are provided for illustrative purpose only and should not be construed to limit the meaning or scope of the disclosure described in the appended claims. Therefore, it will be appreciated by a person having an ordinary skill in the art that various modifications and equivalents can be made from the embodiments. Further, the true scope of the disclosure should be defined by technical details of the appended claims.

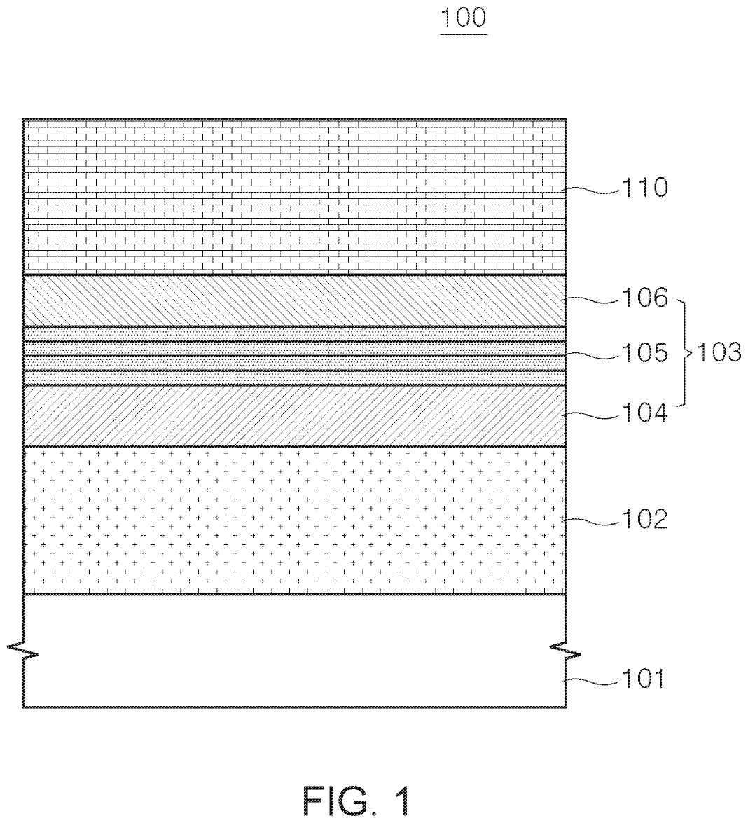

FIG. 1 illustrates a structure of a blankmask according to an embodiment of the disclosure. A blankmask 100 according to the disclosure includes a phase-shift film 102, a light-shielding film 103, and a resist film 110 which are sequentially stacked on a transparent substrate 101. The light-shielding film 103 has a three-layered structure including a first light-shielding film 104 corresponding to a lower layer, a second light-shielding film 105 corresponding to a middle layer, and a third light-shielding film 106 corresponding to an upper layer.

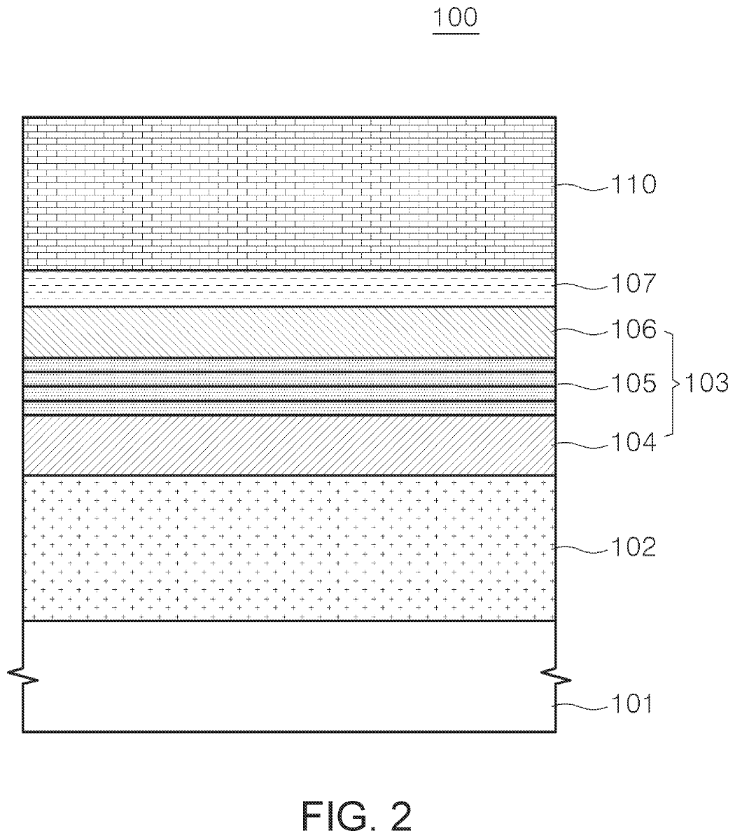

In a case of a binary blankmask, it structured to include the light-shielding film 103 and the resist film 110 without the phase-shift film 102. In a case of a phase-shift blankmask, it is structured to include the phase-shift film 102, the light-shielding film 103, and the resist film 110. FIGS. 1 and 2 illustrate the phase-shift blankmask including the phase-shift film 102, but the disclosure is applicable to both the binary blankmask and the phase-shift blankmask.

FIG. 2 illustrates a structure of a blankmask according to another embodiment of the disclosure, which further includes a hard-mask film 107 in addition to the structure of FIG. 1. As shown in FIG. 2, the disclosure is applicable even to the blankmask 100 including the hard-mask film 107. The blankmask including the hard-mask film 107 may be the binary blankmask including only the light-shielding film 103 without the phase-shift film 102, or the phase-shift blankmask including both the phase-shift film 102 and the light-shielding film 103.

In the embodiments shown in FIGS. 1 and 2, the light-shielding film 103 has the three-layered structure. However, the light-shielding film 103 may be structured to have a single layer, two layers, or four or more layers.

The light-shielding film 103 according to the disclosure includes a compound that contains mainly chromium. The chromium compound shows a tendency to be relatively isotropically etched by a radical reaction when dry-etched with chlorine (Cl)-based gas. For example, in the phase-shift blankmask with the hard-mask film 107, when the hard-mask film 107 is patterned and used as an etch mask to etch the light-shielding film 103 beneath the patterned hard-mask film 107, the radical reaction causes a problem of deviation in critical dimension (CD) between the patterned hard-mask film 107 and the etched light-shielding film 103. Meanwhile, the phase-shift film 102 beneath the light-shielding film 103 includes a molybdenum-silicon compound or a silicon compound, and the phase-shift film 102 in this case has a small CD deviation from the CD of the light-shielding film 103 because an ionic reaction is relatively higher than the radical reaction.

Therefore, to inhibit the radical reaction of the light-shielding film 103, the light-shielding film 103 may contain materials as follows.

The light-shielding film 106 may contain mainly chromium (Cr), and additionally contain one or more kinds of metal selected from a group consisting of molybdenum (Mo), tantalum (Ta), vanadium (V), tin (Sn), cobalt (Co), indium (In), nickel (Ni), zirconium (Zr), niobium (Nb), palladium (Pd), zinc (Zn), aluminum (Al), manganese (Mn), cadmium (Cd), magnesium (Mg), lithium (Li), selenium (Se), copper (Cu), hafnium (Hf) and tungsten (W), and silicon (Si). In particular, the metal added to chromium (Cr) as materials for the light-shielding film 103 may include one or more kinds of elements selected from a group consisting of tantalum (Ta), molybdenum (Mo), tin (Sn), and indium (In). Further, the light-shielding film 103 contains one or more kinds of elements selected from a group consisting of oxygen (O), nitrogen (N), carbon (C) in addition to the metal.

In more detail, according to technical features of the disclosure, the light-shielding film 103 contains mainly chromium (Cr), and an etching speed of the light-shielding film 103 is slowed down to reduce the CD deviation caused by the radical reaction while the light-shielding film 103 is etched. In general, a slow etching speed of the light-shielding film 103 has a problem with deterioration of CD linearity because a loading effect occurs due to pattern density at etching, and therefore a high etching speed of the light-shielding film 103 is preferable. However, the high etching speed causes the foregoing problem of CD deviation at etching, and therefore the disclosure proposes to limit the etching speed of the light-shielding film 103 to no higher than a certain level.

To this end, the light-shielding film 103 of the disclosure is provided as follows.

First, to control the etching speed of the light-shielding film 103, the light-shielding film 103 has a composition ratio of 20˜70 at % chromium, 15˜55 at % nitrogen, 0˜40 at % oxygen, and 0˜30 at % carbon.

In this case, the light-shielding film 103 may have a total thickness of 20˜75 nm, and preferably 30˜60 nm. For example, when the light-shielding film 103 is structured to include two layers, the upper layer may have a thickness of 5˜20 nm, and the lower layer may have a thickness of 30˜50 nm. Alternatively, when the light-shielding film 103 is structured to include three layers, the upper layer has a thickness of 5˜20 nm, the middle layer has a thickness of 5˜30 nm, and the lower layer has a thickness of 5˜20 nm.

Meanwhile, in the phase-shift blankmask, optical density is affected by the transmissivity of the phase-shift film 102 formed beneath the light-shielding film 103. Therefore, the composition ratio and thickness of the phase-shift blankmask may be varied depending on the transmissivity of the phase-shift film 102 formed beneath the light-shielding film 103. That is, the optical density of when the phase-shift film 102 and the light-shielding film 103 are stacked is set to a preferable specific value, and combination of the composition ratio and thickness for the light-shielding film 103 is adjusted based on the transmissivity of the phase-shift film 102 to satisfy the set optical density. The light-shielding film 103, together with the phase-shift film 102, preferably has an optical density of 2.5˜3.5 with respect to an exposure-light wavelength. Further, higher content of nitrogen and oxygen causes the light-shielding film 103 to be thicker in order to satisfy the optical density required for the light-shielding film 103. Meanwhile, the light-shielding film 103 may have reflectivity of no higher than 40%.

First, it will be described that the phase-shift film 102 is formed below having a transmissivity of 3˜10% with respect to exposure light. The optical density required for a structure where the phase-shift film 102 and the light-shielding film 103 are stacked is 2.5 to 3.5. To satisfy such a condition, when the light-shielding film 103 has a thickness of 30˜70 nm, the light-shielding film 103 is formed to have a composition ratio of 20˜70 at % chromium, 15˜55 at % nitrogen, 0˜40 at % oxygen, and 0˜30 at % carbon.

When chromium content is lower than 20 at %, nitrogen and oxygen content is relatively high and thus the etching speed is so high that a problem of the high CD deviation can arise. When the chromium content is higher than 70 at %, the etching speed is slowed down and thus there is a drawback of a great loading effect when the light-shielding film 103 is etched. Accordingly, the chromium content is preferably designed to range from 20 at % to 70 at %. In particular, it is preferable that the chromium content ranges from 30 at % to 70 at %.

Meanwhile, the etching speed increases as the nitrogen and oxygen content becomes higher, and therefore it is preferable to lower the nitrogen and oxygen content to some extent in order to limit the increase of the etching speed. However, when the nitrogen and oxygen content is excessively low, the reflectivity of the light-shielding film 103 increases. Therefore, there is a need of inhibiting the increase of the reflectivity by increasing the nitrogen and oxygen content. That is, the oxygen content and the nitrogen content need to be higher than certain levels so as to prevent the reflectivity from excessively increasing and inhibit the etching speed from excessively increasing. However, oxygen has a greater effect on increasing the etching speed for the content than nitrogen. Thus, nitrogen content may be higher than a certain level, e.g. 15 at %, and oxygen content may be lower than the nitrogen content. In this regard, a composition ratio of 15˜55 at % nitrogen, and 0˜40 at % oxygen is preferable.

Meanwhile, when a large amount of nitrogen and oxygen is contained in the topmost layer for the purpose of decreasing the reflectivity, an oxide film and a nitride film on a surface layer rapidly increase the sheet resistance of the surface layer. Therefore, a pattern shift and the like undesired problems arise due to a charging phenomenon of a thin film during a writing process based on an E-beam. Carbon (C) does not directly prevent such a charging phenomenon, but serves to prevent the sheet resistance from rapidly increasing because carbon (C) causes the sheet resistance to more gently increase than those of nitrogen and oxygen. Further, the etching speed slightly decreases as carbon content increases, and the reflectivity does not show any specific tendency with the carbon content. In this regard, a composition ratio of 0˜30% carbon is preferable.

Next, it will be described that the phase-shift film 102 is formed below having a transmissivity of 30˜100% with respect to exposure light. In this case, to satisfy the optical density of 2.5˜3.5 required for the structure where the light-shielding film 103 and the phase-shift film 102 are stacked, a compensation degree for the optical density of the light-shielding film 103 needs to be higher than that of the phase-shift film 102 having the transmissivity of 3˜10%. To this end, the light-shielding film 103 may have a thickness of 40˜70 nm, and have a composition ratio of chromium 30˜80 at %, 10˜50 at % nitrogen, 0˜35% oxygen, and 0˜25% carbon.

Meanwhile, it is preferable that the optical density of 2.5˜3.5 required for the stacked structure is satisfied even when the phase-shift film 102 is formed below with a transmissivity of 10˜30% that is between the transmissivity of 3˜10% and the transmissivity of 30˜100%.

Thus, the light-shielding film 103 may have a thickness of 35˜65 nm. In this case, the light-shielding film 103 is formed to have a composition of 25˜75% chromium, 5˜45% nitrogen, 0˜30% oxygen, and 0˜20% carbon.

The light-shielding film 103 may have a single layer or a multi-layer including two or more layers. When the light-shielding film 103 is formed to have two or more layers, one or more layers of the layers forming the light-shielding film 103 may have a slower etching speed than the other layers to reduce the CD deviation.

For example, when the light-shielding film 103 is formed to have two layers, the lower layer may have a slower etching speed than the upper layer. Specifically, the upper layer is adjacent to the etch mask and thus has a low CD deviation, but the lower layer has a high CD deviation due to the radical reaction. Therefore, the etching speed of the lower layer needs to be slowed down.

Meanwhile, each of the upper and lower layers in the foregoing two-layered structure according to an embodiment may include a plurality of layers. For example, it will be assumed that the light-shielding film is structured to have five layers from the bottommost first layer to the topmost fifth layer. In this case, the five layers may be roughly divided into two layers with respect to a certain boundary surface, and layers above the boundary surface and layers below the boundary surface may be respectively regarded as the upper layer and the lower layer. Such a case is applied when the same terms as above are used in appended claims.

Alternatively, when the light-shielding film 103 is configured to have three layers as shown in FIGS. 1 and 2, the middle layer may have a slower etching speed than those of the upper layer and the lower layer. Specifically, when the light-shielding film 103 is formed to have three layers, the radical reaction occurs relatively less in the upper layer of the light-shielding film 103, and thus the CD deviation is decreased because an upper etch mask has a high printing rate.

On the other hand, the radical reaction occurs relatively more in the middle layer and the lower layer than that in the upper layer, and thus the CD deviation is increased. Therefore, the middle layer and the lower layer needs to have a slower etching speed than the upper layer so as to inhibit the CD deviation. In this case, a pattern profile is taken into account to decrease the etching speed in the middle layer and increase the etching speed in the lower layer, thereby having an effect on preventing the footing. To this end, the upper layer may contain both nitrogen(N) and oxygen(O) so as to reduce surface reflection, and the lower layer may contain more nitrogen(N) and/or oxygen(O) than the middle layer so as to more improve the etching speed in a depth direction than the middle layer.

Meanwhile, each of the upper, middle and lower layers in the foregoing three-layered structure according to an embodiment may include a plurality of layers. For example, it will be assumed that the light-shielding film is structured to have five layers from the bottommost first layer to the topmost fifth layer. In this case, the five layers may be roughly divided into three layers of the upper layer, the middle layer, and the lower layer with respect to certain two boundary surfaces. Therefore, the upper layer may refer to only the fifth layer, a layer including the fourth and fifth layers, or a layer including the third to fifth layers. Likewise, the middle layer may refer to a layer including the second to fourth layers, a layer including the second and third layers, a layer including the third and fourth layers, only the second layer, or only the third layer. Further, the lower layer may refer to only the first layer, a layer including the first layer and the second layer, or a layer including the first to third layers. Such cases are applied when the same terms as above are used in appended claims.

The light-shielding film 103 may selectively undergo a thermal process at 100˜500° C. after film growth is completed, in order to improve chemical resistance and flatness. The thermal process may be carried out using a hot plate, a vacuum rapid thermal-process apparatus, a furnace, etc.

The phase-shift film 102 and the hard-mask film 107 respectively formed on and beneath the light-shielding film 103 are made of a silicon (Si)-based material including silicon (Si) or transition metal, and include a single layer or a multi-layer or continuous layer having two or more layers.

Specifically, the phase-shift film 102 or the hard-mask film 107 may contain one among Si, SiN, SiC, SiO, SiB, SiCN, SiNO, SiBN, SiCO, SiBC, SiBO, SiNCO, SiBCN, SiBON, SiBCO, SiBCON and the like silicon (Si) compounds. Further, when the transition metal, i.e. molybdenum (Mo) is contained in the phase-shift film 102 or the hard-mask film 107, the phase-shift film 102 or the hard-mask film 107 may contain one among MoSi, MoSiN, MoSiC, MoSiO, MoSiB, MoSiCN, MoSiNO, MoSiBN, MoSiCO, MoSiBC, MoSiBO, MoSiNCO, MoSiBCN, MoSiBON, MoSiBCO, MoSiBCON and the like molybdenum silicide (MoSi) compounds.

The phase-shift film 102 has a transmissivity of 3˜100% with respect to exposure light having a wavelength of 193 nm, and has phase-shift degrees of 160˜230°. Specifically, with respect to the exposure light having the wavelength of 193 nm, a phase-shift mask (PSM) having a transmissivity of 6% shows phase-shift degrees of 160˜200°, a phase-shift mask (PSM) having a transmissivity of 45% shows phase-shift degrees of 175˜215°, and a phase-shift mask (PSM) having a transmissivity of 70% shows phase-shift degrees of 190˜230°.

The phase-shift film 102 may selectively undergo a thermal process at 100˜1000° C. after it is completely grown, in order to improve chemical resistance and flatness. The thermal process may be carried out using a hot plate, a vacuum rapid thermal-process apparatus, a furnace, etc. Alternatively, a sputtering apparatus may also be used to form a thin film that is as effective as the thermal process.

The hard-mask film 107 may be formed to have a thickness of 2˜20 nm. When the thickness is smaller than 2 nm, the hard-mask film 107 is so thin that the surface of the light-shielding film 103 can be damaged when the light-shielding film 103 is etched. When the thickness of the hard-mask film 107 is greater than 20 nm, the resist film 110 needs to become thicker and it is therefore difficult to form a high-precision pattern because of electron scattering during the writing process based on the E-beam.

The resist film 110 may have a thickness of 60˜150 nm, and may include a chemically amplified resist (CAR).

### (Embodiment 1): Manufacture of Phase-Shift Blankmask

This embodiment discloses manufacture of a phase-shift blankmask having no hard-mask film as shown in FIG. 1.

A phase-shift film was formed as a single layer of molybdenum silicon-nitride (MoSiN), by mounting a target, which contains molybdenum silicide (MoSi) of 10:90, injecting process gas of Ar:N₂=5.5 sccm:23.0 sccm, and supplying process power of 0.65 kW to the DC magnetron sputtering apparatus.

Then, the phase-shift film was subjected to a thermal process at a temperature of 350° C. for 20 minutes through the vacuum rapid thermal-process apparatus.

As results of measuring the transmissivity and the phase-shift degree of the phase-shift film with respect to the exposure light having the wavelength of 193 nm, the phase-shift film had a transmissivity 6.02%, and a phase-shift degree of 183.5°. As a result of measuring the thickness of the phase-shift film through the X-ray reflectometry (XRR) apparatus, the phase-shift film had a thickness of 67.5 nm.

Then, a chromium (Cr) target was used with process gas of Ar:N₂:CO₂=3.0 sccm:10.0 sccm:6.5 sccm and process power of 0.62 kW, thereby forming the first light-shielding film of chromium oxynitride (CrON) on the phase-shift film. As a result of measuring the thickness of the first light-shielding film through the XRR apparatus, the first light-shielding film had a thickness of 8.5 nm. Next, to form the second light-shielding film on the first light-shielding film, process gas of Ar:N₂=5.0 sccm:9.0 sccm was injected, and process power of 1.40 kW was supplied, thereby forming the second light-shielding film of chromium nitride (CrN) as thick as 22.0 nm. Next, to form the third light-shielding film on the second light-shielding film, process gas of Ar:N₂:CO₂=3.0 sccm:10.0 sccm:6.0 sccm was injected, and process power of 0.62 kW was supplied, thereby forming the third light-shielding film of chromium oxynitride (CrON). As a result of measuring the thickness of the third light-shielding film through the XRR apparatus, the third light-shielding film had a thickness of 13.0 nm.

The light-shielding film formed by this process had a total thickness of 43.5 nm, and showed an optical density of 3.05 and a reflectivity of 28.8% as a result of measuring the optical density and the reflectivity according to the light-shielding film formed on the phase-shift film with respect to the exposure light having the wavelength of 193 nm. Then, the light-shielding film was subjected to the thermal process at a temperature of 250° C. for 20 minutes through the vacuum rapid thermal-process apparatus.

Next, the composition ratio of the light-shielding film was analyzed through the Auger electron spectroscopy apparatus. In result, it was analyzed that the first light-shielding film contained 38.9 at % chromium (Cr), 22.3 at % nitrogen (N), and 22.3 at % oxygen (O); the second light-shielding film contained 68.9 at % chromium (Cr), and 30.4 at % nitrogen (N); and the third light-shielding film contained 39.4 at % chromium (Cr), 23.1 at % nitrogen (N), 20.4 at % oxygen (O), and 17.1 at % carbon (C).

Then, a chemically amplified resist film was formed on the light-shielding film by spin-coating, and thus the phase-shift blankmask was manufactured.

### (Embodiment 2): Manufacture of Phase-Shift Blankmask with Hard-Mask Film

This embodiment discloses manufacture of a phase-shift blankmask having a hard-mask film as shown in FIG. 2.

The phase-shift film and the light-shielding film were formed like those of the embodiment 1.

Subsequently, to form the hard-mask film on the light-shielding film, a silicon (Si) target doped with boron (B) was used with injected process gas of Ar:N₂:NO=7.0 sccm:7.0 sccm:5.0 sccm, and supplied process power of 0.7 kW, thereby forming the hard-mask film of silicon oxynitride (SiON) as much as 10 nm.

Then, a chemically amplified resist film was formed on the hard-mask film by spin-coating, and thus the phase-shift blankmask was manufactured.

As a result of performing an etching process with mixture gas of chlorine (Cl) and oxygen (O) through the TETRA-X apparatus, a 6% phase-shift blankmask having a thickness of 43.5 nm had an etch rate of 1.21 ÅA/sec.

### Comparative Example 1

This comparative example discloses manufacture of a phase-shift blankmask formed with a light-shielding film, an etch rate of which is higher than those of the embodiments 1 and 2.

The phase-shift film was formed like the embodiment 1.

Then, a chromium (Cr) target was used with process gas of Ar:N₂:CO₂=6.0 sccm:10.0 sccm:6.0 sccm and process power of 0.75 kW, thereby forming the first light-shielding film of chromium carbide oxynitride (CrCON) on the phase-shift film. As a result of measuring the thickness of the first light-shielding film through the XRR apparatus, the first light-shielding film had a thickness of 40.0 nm. Next, to form the second light-shielding film on the first light-shielding film, process gas of Ar:N₂:CO₂=5.0 sccm:5.0 sccm:2.0 sccm was injected, and process power of 1.40 kW was supplied, thereby forming the second light-shielding film of chromium carbide oxynitride (CrCON) as thick as 4.3 nm. Next, to form the third light-shielding film on the second light-shielding film, process gas of Ar:N₂:CO₂=3.0 sccm:10.0 sccm:7.5 sccm was injected, and process power of 0.75 kW was supplied, thereby forming the third light-shielding film of chrome carbide oxynitride (CrCON). As a result of measuring the thickness of the third light-shielding film through the XRR apparatus, the third light-shielding film had a thickness of 4.2 nm.

The formed light-shielding film had a total thickness of 48.5 nm, and showed an optical density of 3.03 and a reflectivity of 27.9% as a result of measuring the optical density and the reflectivity according to the light-shielding film formed on the phase-shift film with respect to the exposure light having the wavelength of 193 nm.

Next, the composition ratio of the light-shielding film was analyzed through the Auger electron spectroscopy apparatus. In result, it was analyzed that the first light-shielding film contained 41.5 at % chrome (Cr), 22.9 at % nitrogen (N), 19.0 at % oxygen (O), and 16.6 at % carbon (C); the second light-shielding film contained 54.9 at % chrome (Cr), 27.4 at % nitrogen (N), 3.7 at % oxygen(0), and 14.0 at % carbon(C); and the third light-shielding film contained 40.3 at % chrome (Cr), 23.0 at % nitrogen (N), 20.4 at % oxygen (O), and 16.3 at % carbon (C).

Then, a chemically amplified resist film was formed on the light-shielding film by spin-coating, and thus the phase-shift blankmask was manufactured.

### Comparative Example 2

This comparative example discloses manufacture of a phase-shift blankmask having a hard-mask film formed with a light-shielding film, an etch rate of which is higher than those of the embodiments 1 and 2.

The phase-shift film and the light-shielding film were formed like the comparative example 1.

Subsequently, to form the hard-mask film on the light-shielding film, a silicon (Si) target doped with boron (B) was used with injected process gas of Ar:N₂:NO=7.0 sccm:7.0 sccm:5.0 sccm, and supplied process power of 0.7 kW, thereby forming the hard-mask film of silicon oxynitride (SiON) as much as 10 nm.

Then, a chemically amplified resist film was formed on the hard-mask film by spin-coating, and thus the phase-shift blankmask was manufactured.

As a result of performing an etching process with mixture gas of chlorine (Cl) and oxygen (O) through the TETRA-X apparatus, a 6% phase-shift blankmask having a thickness of 48.5 nm had an etch rate of 1.83 ÅA/sec.

### (Embodiment 3): Manufacture of Phase-Shift Blankmask with a 70% (High Transmissivity) Hard-Mask Film

This embodiment discloses a phase-shift blankmask of which the phase-shift film and the light-shielding film are different in structure from those of the embodiments 1 and 2.

A phase-shift film was formed as a single layer of silicide oxynitride (SiON), by using a silicon (Si) target doped with boron (b), injecting process gas of Ar:N₂ NO=5.0 sccm:5.0 sccm:5.0 sccm, and supplying process power of 1.0 kW to a DC magnetron sputtering apparatus.

Then, the phase-shift film was subjected to a thermal process at a temperature of 500° C. for 40 minutes through the vacuum rapid thermal-process apparatus. As results of measuring the transmissivity and the phase-shift degree of the phase-shift film with respect to the exposure light having the wavelength of 193 nm, the phase-shift film had a transmissivity 71.0%, and a phase-shift degree of 215.5°. As a result of measuring the thickness of the phase-shift film through the XRR apparatus, the phase-shift film had a thickness of 127.1 nm.

Then, a chrome (Cr) target was used with process gas of Ar:N₂:CH₄=5.0 sccm:5.0 sccm:0.8 sccm and process power of 1.40 kW, thereby forming the first light-shielding film of chrome carbonitride (CrCN) on the phase-shift film. As a result of measuring the thickness of the first light-shielding film through the XRR apparatus, the first light-shielding film had a thickness of 41.5 nm. Next, to form the second light-shielding film on the first light-shielding film, process gas of Ar:N₂:NO=3.0 sccm:10.0 sccm:5.7 sccm was injected, and process power of 0.62 kW was supplied, thereby forming the second light-shielding film of chrome oxynitride (CrON) as thick as 18.0 nm.

The formed light-shielding film had a total thickness of 59.5 nm, and showed an optical density of 3.09 and a reflectivity of 32.8% as a result of measuring the optical density and the reflectivity according to the light-shielding film formed on the phase-shift film with respect to the exposure light having a wavelength of 193 nm.

Subsequently, a silicon (Si) target doped with boron (B) was used with injected process gas of Ar:N₂:NO=7.0 sccm:7.0 sccm:5.0 sccm, and supplied process power of 0.7 kW, thereby forming the hard-mask film of silicon oxynitride (SiON) as much as 10 nm on the light-shielding film.

Then, a chemically amplified resist film was formed on the hard-mask film by spin-coating, and thus the phase-shift blankmask was manufactured.

As a result of performing an etching process with mixture gas of chlorine (Cl) and oxygen (O) through the TETRA-X apparatus, a 70% (high transmissivity) phase-shift blankmask having a thickness of 59.5 nm had an etch rate of 0.71 ÅA/sec.

Evaluation of Measured CD Deviation of Light-Shielding Film

The optical density of the foregoing phase-shift blankmask according to the disclosure and the CD deviation after patterning the light-shielding film were measured.

Table 1 shows thin film properties of the blankmask. Referring to Table 1, the blankmasks of both the embodiments and the comparative examples showed the optical density of 2.5˜3.5 together with the phase-shift film and were thus appropriate for the photomask after forming the pattern thereon, and nothing unusual was found with regard to thin film properties.

TABLE 1

| | | | | | | | | comparative | | comparative | |
|---|---|---|---|---|---|---|---|---|---|---|---|
| | | Embodiment 1 | | Embodiment 2 | | Embodiment 3 | | example 1 | | example 2 | |
| Phase- | Materials | MoSiN | | MoSiN | | SiON | | MoSiN | | MoSiN | |
| shift | Thickness | 67.5 | nm | 67.5 | nm | 127.1 | nm | 67.5 | nm | 67.5 | nm |
| film | Transmissivity | 6.02% | | 6.01% | | 71.0% | | 6.05% | | 6.03% | |
| properties | Phase | 183.5° | | 183.6° | | 215.5° | | 183.1° | | 183.3° | |
| Light- | w/PSM | 3.05 | | 3.06 | | 3.09 | | 3.03 | | 3.04 | |
| shielding | Reflectivity | 28.8% | | 29.0% | | 32.8% | | 27.9% | | 28.1% | |
| film | | | | | | | | | | | |
| OD/ | | | | | | | | | | | |
| Reflectivity | | | | | | | | | | | |
| Light- | Third | 13.0 | nm | 13.0 | nm | — | | 4.2 | nm | 4.2 | nm |
| shielding | thickness | | | | | | | | | | |
| film | Second | 22.0 | nm | 22.0 | nm | 18.0 | nm | 4.3 | nm | 4.3 | nm |
| Thickness | film | | | | | | | | | | |
| | thickness | | | | | | | | | | |
| | First | 8.5 | nm | 8.5 | nm | 41.5 | nm | 40.0 | nm | 40.0 | nm |
| | film | | | | | | | | | | |
| | Thickness | | | | | | | | | | |
| Hard- | Materials | X | | SiON | | SiON | | X | | SiON | |
| mask | Thickness | — | | 10 | nm | 10 | nm | — | | 10 | nm |
| film | | | | | | | | | | | |
| Resist | Thickness | 150 | nm | 100 | nm | 100 | nm | 150 | nm | 100 | nm |

In terms of manufacturing the photomask, a resist for the E-beam, i.e. the chemically amplified resist generally used for micropatterning was applied to the blankmask, and the thicknesses thereof are tabulated in Table 1.

By using the applied resist as an etch mask, the hard-mask film was patterned with fluorine-based mixture etch gas after writing and developing processes. By using the hard-mask film as an etch mask, the light-shielding film was patterned with mixture etch gas of chlorine and oxygen (oxide). By using the light-shielding film as an etch mask, the phase-shift film was patterned with the fluorine-based etch gas. In result, the photomask was manufactured.

TABLE 2

| | Comparative | | | | | |
|---|---|---|---|---|---|---|
| | example 2 | | Embodiment 2 | | Embodiment 3 | |
| Properties | 6% HM PSM | | 6% HM PSM | | 70% HM PSM | |
| Resist CD | 100 | nm | 100 | nm | 100 | nm |
| (L/S) | | | | | | |
| ABS Layer CD | 63 | nm | 89 | nm | 92 | nm |
| ABS Structure | 3 Layer | | 3 Layer | | 2 Layer | |
| Skew (@ABS) | 37 | nm | 11 | nm | 8 | nm |
| PSM Layer CD | 59 | nm | 85 | nm | 88 | nm |
| ABS Layer E/R | 1.83 | ÅA/s | 1.21 | ÅA/s | 0.71 | ÅA/s |

Table 2 shows CD deviations and skewed degrees of blankmask thin films (O/E of 30% was applied to the CD of the ABS Layer in consideration of EPD, and the CD was measured after etching).

Table 2 shows results of a resist patterning for 100 nm line & space CD check with four kinds of etching masks. It could be understood that the skewed degrees are varied depending on the etch rates and the structure of the light-shielding film, and it is therefore easy to control the skewed degrees.

According to the disclosure, it is possible to minimize the CD deviation of the light-shielding film by controlling the etching speed of the light-shielding film. Thus, a high-quality blankmask and a high-quality photomask using the same are manufactured.

Although the disclosure has been shown and described with exemplary embodiments, the technical scope of the disclosure is not limited to the scope disclosed in the foregoing embodiments. Therefore, it will be appreciated by a person having an ordinary skill in the art that various changes and modifications may be made from these exemplary embodiments. Further, it will be apparent as defined in the appended claims that such changes and modifications are involved in the technical scope of the disclosure.

### REFERENCE NUMERALS

100: the blankmask
101: the transparent substrate
102: the phase-shift film
103: the light-shielding film
104: the first light-shielding film
105: the second light-shielding film
106: the third light-shielding film
107: the hard-mask film
110: the resist film

What is claimed is:

1. A blankmask comprising:
a transparent substrate; and
a light-shielding film formed on the transparent substrate,
the light-shielding film having a composition ratio of 20˜70 at % chromium, 15˜55 at % nitrogen, 0˜40 at % oxygen, and 0˜30 at % carbon.

2. The blankmask according to claim 1, further comprising a phase-shift film formed on the transparent substrate and beneath the light-shielding film,
the phase-shift film having a transmissivity of 3˜10% with respect to exposure light.

3. The blankmask according to claim 2, wherein a structure where the light-shielding film and the phase-shift film are stacked has an optical density of 2.5˜3.5.

4. The blankmask according to claim 3, wherein the light-shielding film has a thickness of 30˜70 nm.

5. A blankmask comprising:
a transparent substrate;
a phase-shift film formed on the transparent substrate; and
a light-shielding film formed on the phase-shift film,
the phase-shift film having a transmissivity of 30˜100%, and
the light-shielding film having a composition ratio of 30˜80 at % chromium, 10˜50 at % nitrogen, 0˜35% oxygen, and 0˜25% carbon.

6. The blankmask according to claim 5, wherein a structure where the light-shielding film and the phase-shift film are stacked has an optical density of 2.5˜3.5.

7. The blankmask according to claim 6, wherein the light-shielding film has a thickness of 40˜70 nm.

8. A blankmask comprising:
a transparent substrate;
a phase-shift film formed on the transparent substrate; and
a light-shielding film formed on the phase-shift film,
the phase-shift film having a transmissivity of 10˜30%, and
the light-shielding film having a composition ratio of 25˜75 at % chromium, 5˜45 at % nitrogen, 0˜30% oxygen, and 0˜20% carbon with respect to exposure light.

9. The blankmask according to claim 8, wherein a structure where the light-shielding film and the phase-shift film are stacked has an optical density of 2.5˜3.5.

10. The blankmask according to claim 9, wherein the light-shielding film has a thickness of 35˜65 nm.

11. The blankmask according to claim 1, wherein the light-shielding film comprises a multi-layer comprising two or more layers.

12. The blankmask according to claim 11, wherein
the light-shielding film comprises two layers of an upper layer and a lower layer, and
the lower layer has a slower etching speed than the upper layer.

13. The blankmask according to claim 11, wherein
the light-shielding film comprises three layers of an upper layer, a middle layer, and a lower layer, and
the middle layer has a slower etching speed than the upper layer and the lower layer.

14. The blankmask according to claim 11, wherein
the light-shielding film comprises three layers of an upper layer, a middle layer, and a lower layer, and
the middle layer and the lower layer have a slower etching speed than the upper layer.

15. The blankmask according to claim 14, wherein the upper layer comprises nitrogen (N) and oxygen (O).

16. The blankmask according to claim 14, wherein the lower layer has a faster etching speed than the middle layer.

17. The blankmask according to claim 16, wherein the lower layer comprises more nitrogen (N) and/or oxygen (O) than the middle layer.

18. The blankmask according to claim 1, wherein the phase-shift film comprises silicon (Si) or a silicon (Si)-based material comprising transition metal.

19. The blankmask according to claim 1, further comprising a hard-mask film formed on the light-shielding film.

20. The blankmask according to claim 19, wherein the hard-mask film comprises silicon (Si) or a silicon (Si)-based material comprising transition metal.

21. A photomask manufactured using the blankmask according to claim 1.
